(19) United States
(12) Patent Application Publication
(10) Pub. No.: US 2025/0063738 A1
(43) Pub. Date: Feb. 20, 2025

(54) SEMICONDUCTOR MEMORY DEVICE AND METHOD OF MANUFACTURING THE SAME

(71) Applicant: Samsung Electronics Co., Ltd., Suwon-si (KR)

(72) Inventors: Seulji Song, Suwon-si (KR); Hwayeong Lee, Suwon-si (KR)

(21) Appl. No.: 18/801,958

(22) Filed: Aug. 13, 2024

(30) Foreign Application Priority Data
Aug. 14, 2023 (KR) 10-2023-0106461

(51) Int. Cl. H10B 53/30

(52) U.S. Cl. CPC H10B 53/30

(57) ABSTRACT

A semiconductor memory device includes an active portion, a pad insulating layer on the active portion and including a pad through hole, a landing pad in the pad through hole and electrically connected to the active portion, and the landing pad including a protrusion protruding towards an upper portion of the pad insulating layer, a lower conductive layer on the pad insulating layer and bordering a side surface of the protrusion of the landing pad, a lower electrode on the landing pad and electrically connected to the landing pad, a ferroelectric layer on the lower conductive layer and bordering the lower electrode, an upper electrode bordering the ferroelectric layer, an electrode insulating layer on the upper electrode, a plate line on the electrode insulating layer and the upper electrode and electrically connected to the upper electrode, wherein the plate line is electrically connected to the lower conductive layer through a through via.

### CROSS-REFERENCE TO RELATED APPLICATION

This application is based on and claims priority under 35 U.S.C. § 119 to Korean Patent Application No. 10-2023-0106461, filed on Aug. 14, 2023, in the Korean Intellectual Property Office, the disclosure of which is incorporated by reference herein in its entirety.

### BACKGROUND

The inventive concept relates to a semiconductor memory device and a method of manufacturing the same, and more particularly, to a semiconductor memory device including a ferroelectric layer and a method of manufacturing the semiconductor memory device.

As semiconductor memory devices have become increasingly integrated, individual circuit patterns have been further miniaturized to accommodate a greater number of semiconductor memory devices in the same area. That is, as the integration degree of semiconductor memory devices has increased, the design rules regarding the components of the semiconductor memory devices have been reduced.

With regard to a highly scaled semiconductor memory device, the process of producing a capacitor tends to be complicated and difficult. Securing a desired capacitance in a miniaturized semiconductor device with a capacitor having a well-known structure has generally reached its limits.

### SUMMARY

The inventive concept may provide a semiconductor memory device in which depolarization is restricted as leakage of electric charges from a lower electrode is controlled, and a method of manufacturing the semiconductor memory device.

The inventive concept may provide a semiconductor memory device with reduced manufacturing costs by simplifying manufacturing processes, and a method of manufacturing the semiconductor memory device.

Technical problems to be solved by the inventive concept are not limited to the above description, and other technical problems may be clearly understood by one of ordinary skill in the art from the descriptions provided hereinafter.

According to an aspect of the inventive concept, there is provided a semiconductor memory device including an active portion, a pad insulating layer on the active portion and including a pad through hole, a landing pad in the pad through hole and electrically connected to the active portion, the landing pad including a protrusion protruding towards an upper portion of the pad insulating layer, a lower conductive layer on the pad insulating layer and bordering a side surface of the protrusion of the landing pad, a lower electrode on the landing pad and electrically connected to the landing pad, a ferroelectric layer on the lower conductive layer and bordering the lower electrode, an upper electrode bordering the ferroelectric layer, an electrode insulating layer on the upper electrode, a plate line on the electrode insulating layer and the upper electrode and electrically connected to the upper electrode and the plate line is electrically connected to the lower conductive layer through a through via.

According to another aspect of the inventive concept, there is provided a semiconductor memory device including a plurality of bit lines extending in a first direction and spaced apart from each other in a second direction perpendicular to the first direction, a plurality of active portions, at least two of the plurality of active portions being on the plurality of bit lines, respectively, a pad insulating layer on the plurality of active portions and including a plurality of pad through holes corresponding to the plurality of active portions, a plurality of landing pads in the plurality of pad through holes and electrically connected to the plurality of active portions, respectively, and including a plurality of protrusions protruding towards an upper portion of the pad insulating layer, a lower conductive layer bordering side surfaces of the plurality of protrusions of the plurality of landing pads, a plurality of lower electrodes on the plurality of landing pads, respectively, and electrically connected to the plurality of landing pads, a ferroelectric layer bordering the plurality of lower electrodes and being on the lower conductive layer, an upper electrode bordering the ferroelectric layer, an electrode insulating layer on the upper electrode, and a plate line on the electrode insulating layer and the upper electrode and electrically connected to the upper electrode, the plate line is electrically connected to the lower conductive layer through a through via, and the lower conductive layer, the through via, and the plate line electrically connect the lower electrode to the upper electrode when the active portion is in an off-state.

According to another aspect of the inventive concept, there is provided a semiconductor memory device including a plurality of bit lines extending in a first direction and spaced apart from each other in a second direction perpendicular to the first direction, a plurality of word lines extending in the second direction and spaced apart from each other in the first direction, a plurality of active portions, at least two of the plurality of active portions being on the plurality of bit lines, respectively, a plurality of gate insulating layers on both sides of the plurality of active portions, respectively, a pad insulating layer on the plurality of active portions and including a plurality of pad through holes corresponding to the plurality of active portions, a plurality of landing pads in the plurality of pad through holes and electrically connected to the plurality of active portions, respectively, and including a plurality of protrusions protruding towards an upper portion of the pad insulating layer, a lower conductive layer bordering side surfaces of the plurality of protrusions of the plurality of landing pads, a plurality of lower electrodes on the plurality of landing pads, respectively, and electrically connected to the plurality of landing pads, a ferroelectric layer bordering the plurality of lower electrodes and being on the lower conductive layer, an upper electrode bordering the ferroelectric layer, an electrode insulating layer on the upper electrode, and a plate line on the electrode insulating layer and the upper electrode and electrically connected to the upper electrode, the plurality of word lines are spaced apart from the plurality of active portions with the plurality of gate insulating layers therebetween, a width of the plurality of protrusions in the first direction is greater than a width of a portion of the plurality of landing pads in the first direction that is located in the plurality of pad through holes, and the plate line is electrically connected to the lower conductive layer through a through via with a greater width in the first direction than the lower conductive layer.

### BRIEF DESCRIPTION OF THE DRAWINGS

Embodiments will be more clearly understood from the following detailed description taken in conjunction with the accompanying drawings in which:

FIG. 1 is an equivalent circuit diagram showing a cell array of a semiconductor memory device, according to an embodiment;

FIG. 2 is a schematic perspective view of a semiconductor memory device according to an embodiment;

FIG. 3 is a schematic layout of the semiconductor memory device of FIG. 2;

FIG. 4 is a schematic cross-sectional view of the semiconductor memory device of FIG. 3, taken along a line A-A′ of FIG. 3;

FIG. 5 is an enlarged view of a region “EX1” of the semiconductor memory device of FIG. 4;

FIG. 6 is a schematic cross-sectional view of a semiconductor memory device according to an embodiment, taken along the line A-A′ of FIG. 3;

FIG. 7 is a schematic perspective view of a semiconductor memory device according to an embodiment;

FIG. 8 is a schematic layout of the semiconductor memory device of FIG. 7;

FIG. 9 is a schematic cross-sectional view of the semiconductor memory device of FIG. 8 taken along a line B-B′ of FIG. 8;

FIG. 10 is a schematic cross-sectional view of a semiconductor memory device according to an embodiment, taken along the line B-B′ of FIG. 8; and

FIGS. 11 to 22 are diagrams showing a method of manufacturing a semiconductor memory device in an example process order, according to an embodiment.

### DETAILED DESCRIPTION OF THE EMBODIMENTS

As the disclosure allows for various changes and numerous embodiments, particular embodiments will be shown in the drawings and described in detail in the written description. However, it is not intended to limit the present embodiments to specific embodiments. Like reference numerals in the drawings denote like elements, and thus their description will be omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

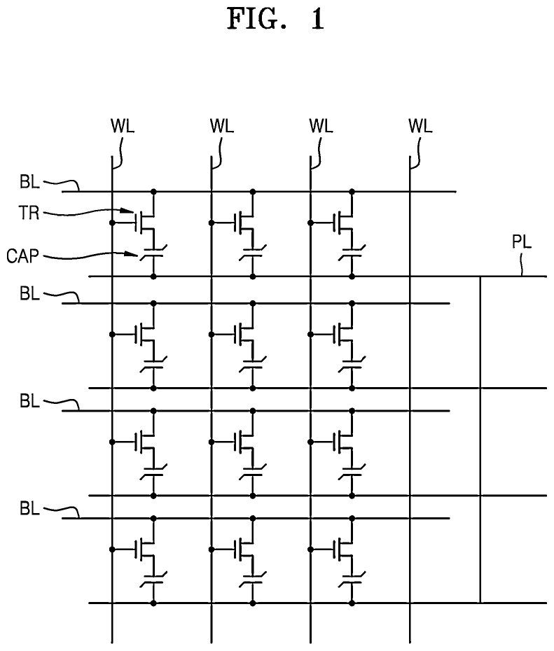

FIG. 1 is an equivalent circuit diagram showing a cell array of a semiconductor memory device, according to an embodiment.

Referring to FIG. 1, the cell array may include one or more semiconductor memory devices (e.g., a transistor TR and a capacitor CAP) that are programmable to store different logic states. In some embodiments, each semiconductor memory device may be programmable to store at least two logic states. For example, the semiconductor memory device may be configured to store one bit (e.g., logic 0 and logic 1) of information at a time. In some cases, a single semiconductor memory device (e.g., a multi-level memory cell) may be configured to store at least two bits (e.g., logic 00, logic 01, logic 10, or logic 11) of information at a time.

Each semiconductor memory device may store a state indicating digital data (e.g., a polarizing state of a ferroelectric layer). In a FeRAM architecture, a semiconductor memory device may include a capacitor CAP including electric charges indicating a programmable state and/or a ferroelectric material for storing polarization.

By activating or selecting word lines WL, bit lines BL, and/or plate lines PL, operations, such as a read operation and a write operation, may be performed on the semiconductor memory device. The activation or selection of the word lines WL, the bit lines BL, or the plate lines PL may include applying a voltage to each line.

The cell array may include the word lines WL, the bit lines BL, and the plate lines PL that are arranged in a grid pattern. The semiconductor memory device may be located at an intersection point of the word line WL, the bit line BL, and/or the plate line PL. By applying voltage to the word line WL, the bit line BL, and the plate line PL, a semiconductor memory located at the intersection point thereof may be selected. In some embodiments, the plate line PL may be configured to apply the same voltage to capacitors CAP of a plurality of semiconductor memory devices.

However, during a write operation of one semiconductor memory device of the cell array, a logic state of a capacitor CAP of an unselected semiconductor memory device may deteriorate or be destructive. For example, in the case of a FeRAM architecture in which a semiconductor memory device includes a ferroelectric material, electric charges may leak to bit lines BL from a capacitor CAP, and thus, a ferroelectric layer of the capacitor CAP may be depolarized.

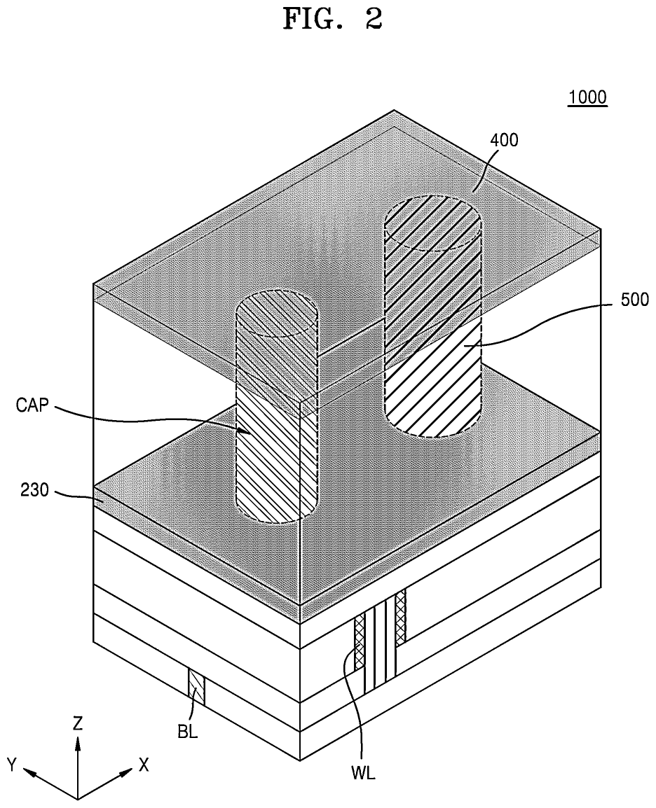

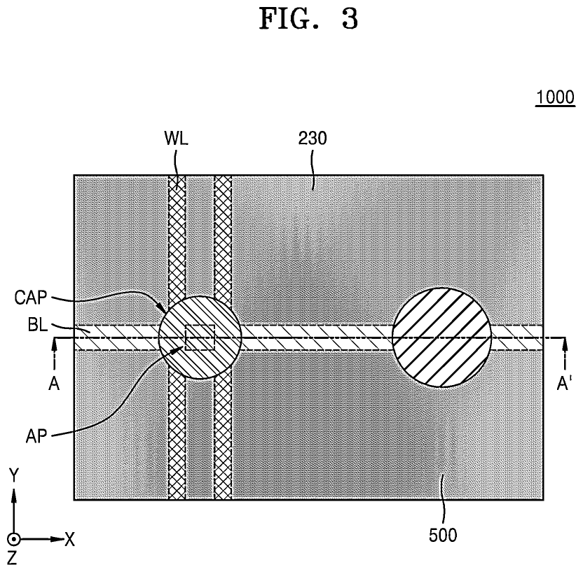

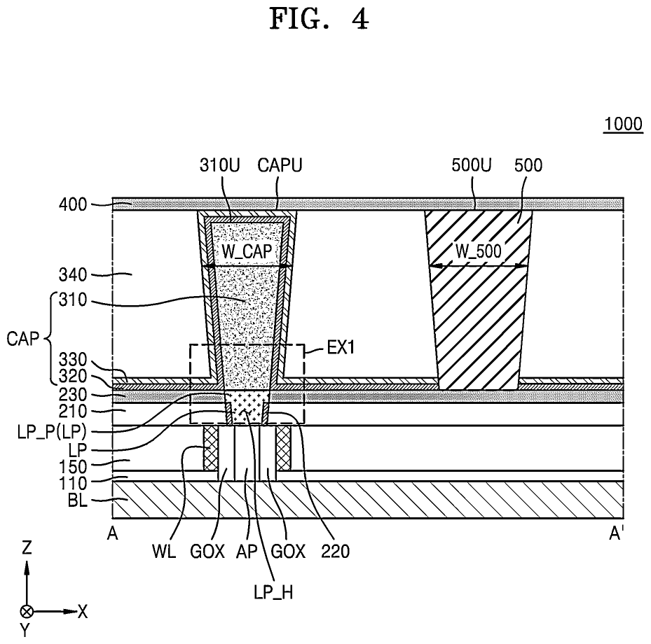

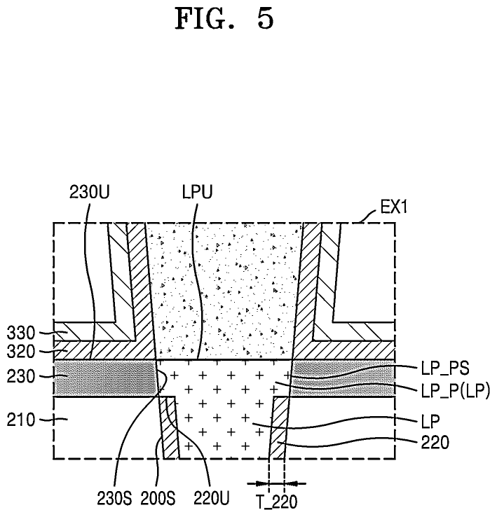

FIG. 2 is a schematic perspective view of a semiconductor memory device 1000 according to an embodiment. FIG. 3 is a schematic layout of the semiconductor memory device 1000 of FIG. 2. FIG. 4 is a schematic cross-sectional view of the semiconductor memory device 1000 of FIG. 3 taken along a line A-A′ of FIG. 3. FIG. 5 is an enlarged view of a region “EX1” of the semiconductor memory device 1000 of FIG. 4.

Referring to FIGS. 2 to 5, the semiconductor memory device 1000 may include an active portion AP, a pad insulating layer 210, a landing pad LP, a lower conductive layer 230, a capacitor CAP, and a plate line 400.

Hereinafter, unless otherwise specifically defined, a direction in which the bit line BL extends may be defined as a first direction (an X direction), a direction perpendicular to an upper surface of the bit line BL may be defined as a vertical direction (a Z direction), and a direction perpendicular to the first direction (the X direction) and the vertical direction (the Z direction) may be defined as a second direction (a Y direction).

The semiconductor memory device 1000 may include the bit line BL and the word line WL. The bit line BL may extend in the first direction (the X direction), and the word line WL may extend in the second direction. That is, the bit line BL may extend in a direction perpendicular to the word line WL. The bit line BL and the word line WL may be spaced apart from each other in the vertical direction (the Z direction) with a line insulating layer 110 therebetween. For example, the word line WL may be protected from the outside by an insulating layer 150 that is on and at least partially covers the line insulating layer 110 and borders or at least partially surrounds a side surface of the word line WL. For example, the bit line BL may be configured to transmit a signal to the active portion AP, and the word line WL may be configured to transmit a signal to a gate insulating layer GOX.

The active portion AP of the semiconductor memory device 1000 may be formed on the bit line BL. The gate insulating layer GOX of the semiconductor memory device 1000 may be arranged between the word line WL and the active portion AP. The active portion AP and the gate insulating layer GOX may be referred to as one transistor.

Hereinafter, the semiconductor memory device 1000 is described as including a vertical transistor, but embodiments of the semiconductor memory device 1000 are not limited to specific types of transistors, and may include, for example, a fin transistor or a planar transistor.

In some embodiments, the active portion AP may contact the bit line BL and extend in the vertical direction (the Z direction). The active portion AP may include a first dopant area adjacent to the bit line BL, a second dopant area spaced apart from the first dopant area in the vertical direction (the Z direction), and a channel area located between the first dopant area and the second dopant area. For example, the first dopant area may be referred to as a source area, and the second dopant area may be referred to as a drain area.

In some embodiments, the channel area of the active portion AP may be controlled by the word line WL when the semiconductor memory device 1000 operates. For example, when current flows in the word line WL, the active portion AP may be in an on-state. When no current flows in the word line WL, the active portion AP may be in an off-state. That is, a resistance value of the active portion AP in the on-state may be less than that of the active portion AP in the off-state. In some embodiments, when the active portion AP is in the on-state, the active portion AP may be configured to transmit a signal from the bit line BL to the lower electrode 310 in. When the active portion AP is in the off-state, although a signal is transmitted from the bit line BL, the active portion AP may be configured not to transmit the signal to the lower electrode 310.

In some embodiments, the gate insulating layer GOX may be formed as a pair, and the pair may be located on both sides of the active portion AP. The gate insulating layer GOX may be arranged between the word line WL and the active portion AP and extend in parallel with the word line WL in the second direction (the Y direction). In some embodiments, a length of the gate insulating layer GOX in the vertical direction (the Z direction) may be the same as a length of the active portion AP in the vertical direction (the Z direction).

In some embodiments, the gate insulating layer GOX may include a silicon oxide layer, a silicon oxynitride layer, a high-k dielectric layer having a greater dielectric constant than the silicon oxide layer, or a combination thereof. The high-k dielectric layer may include metal oxide or metal oxynitride. For example, the high-k dielectric layer that may be used as the gate insulating layer GOX may include HfO₂, HfSiO, HfSiON, HfTaO, HfTiO, HfZrO, ZrO₂, Al₂O₃, or a combination thereof, but one or more embodiments are not limited thereto.

The pad insulating layer 210 of the semiconductor memory device 1000 may be formed on the active portion AP. In detail, the pad insulating layer 210 may be formed on the active portion AP, the gate insulating layer GOX, and the insulating layer 150.

The pad insulating layer 210 may include a pad through hole LP_H. The pad through hole LP_H may extend from an upper surface of the pad insulating layer 210 to a lower surface thereof and may be formed in the active portion AP. Accordingly, the landing pad LP at least partially filling the pad through hole LP_H may directly contact the active portion AP. In some embodiments, the pad through hole LP_H may have a horizontal width, i.e., width in the X direction, decreasing closer to the active portion AP.

In some embodiments, materials forming the pad insulating layer 210 may include SiN, SiO, SiCN, SiBN, SiON, SiOCN, SiBCN, SiOC, or a combination thereof.

In some embodiments, the semiconductor memory device 1000 may further include a spacer 220 located inside the pad through hole LP_H. For example, the spacer 220 may be formed on a side surface 210S of the pad insulating layer 210 defining the pad through hole LP_H.

An upper surface 220U of the spacer 220 may be coplanar with the upper surface of the pad insulating layer 210. In some embodiments, a protrusion LP_P of the landing pad LP may be on and at least partially cover the upper surface 220U of the spacer 220. For example, a horizontal width, i.e., width in the X direction, of the protrusion LP_P of the landing pad LP may be greater than that of the pad through hole LP_H. A cross-section of the landing pad LP may be shaped in a hammer.

In the present specification, a thickness T_220 of the spacer 220 refers to a distance between a side surface of the spacer 220, which contacts the pad insulating layer 210, and a side surface of the spacer 220, which contacts the landing pad LP.

In some embodiments, the spacer 220 may be conformally formed on the side surface 210S of the pad insulating layer 210 that defines the pad through hole LP_H. That is, the thickness T_220 of the spacer 220 may be uniform. However, one or more embodiments are not limited thereto, and in some embodiments, the thickness T_220 of the spacer 220 may decrease closer to the active portion AP.

The landing pad LP of the semiconductor memory device 1000 may at least partially fill the pad through hole LP_H. The landing pad LP may include the protrusion LP_P protruding upwards the pad insulating layer 210. The portion of the landing pad LP, which is located inside the pad through hole LP_H, and the protrusion LP_P are formed through the same process and thus may be integrally or monolithically formed as a single body.

The landing pad LP may directly contact the active portion AP. The landing pad LP may be electrically connected to the active portion AP. The landing pad LP may be a portion that establishes an electrical connection between the active portion AP and the capacitor CAP.

The lower conductive layer 230 of the semiconductor memory device 1000 may be formed on the pad insulating layer 210. The lower conductive layer 230 may border and at least partially surround a side surface LP_PS of the protrusion LP_P of the landing pad LP. The lower conductive layer 230 may directly contact the landing pad LP and be electrically connected thereto.

Accordingly, the lower conductive layer 230 may be electrically connected to a lower electrode 310 through the landing pad LP. However, a resistance value of the lower conductive layer 230 may be greater than a resistance value of the lower electrode 310 and a resistance value of the landing pad LP. That is, because the amount of electric charges moving along the lower conductive layer 230 may be small, the capacitor CAP may normally perform a write operation despite the electrical connection of the lower conductive layer 230 with the upper electrode 330 and the lower electrode 310.

The lower conductive layer 230 may include a through hole in which the protrusion LP_P of the landing pad LP is formed. In some embodiments, like the pad through hole LP_H, the through hole of the lower conductive layer 230, in which the protrusion LP_P of the landing pad LP is formed, may have a horizontal width, i.e., a width in the X direction, decreasing closer to the pad insulating layer 210.

In some embodiments, a side surface 230S of the lower conductive layer 230, which contacts the protrusion LP_P of the landing pad LP, may be coplanar with the side surface 210S of the pad insulating layer 210 that defines the pad through hole LP_H. For example, the through hole, which includes therein the protrusion LP_P of the landing pad LP, and the pad through hole LP_H of the pad insulating layer 210 may be formed through the same process. Accordingly, the inner wall of the through hole, which includes therein the protrusion LP_P of the landing pad LP, may be coplanar with the inner wall of the pad through hole LP_H of the pad insulating layer 210.

In some embodiments, an upper surface 230U of the lower conductive layer 230 may be coplanar with an upper surface LPU of the landing pad LP. In detail, the upper surface 230U of the lower conductive layer 230 may be coplanar with the upper surface of the protrusion LP_P of the landing pad LP.

The capacitor CAP of the semiconductor memory device 1000 may include the lower electrode 310, a ferroelectric layer 320, and the upper electrode 330.

The lower electrode 310 of the capacitor CAP may be formed on the landing pad LP. For example, the lower electrode 310 may protrude from the landing pad LP in the vertical direction (the Z direction). The length of the lower electrode 310 in the vertical direction (the Z direction) may be relatively much greater than the diameter thereof. The lower electrode 310 may be electrically connected to the landing pad LP. The lower electrode 310 may be electrically connected to the active portion AP through the landing pad LP. Accordingly, electric charges move from the active portion AP to the lower electrode 310, and thus, the charges may be charged and discharged in the lower electrode 310.

The ferroelectric layer 320 of the capacitor CAP may be on and at least partially cover the lower conductive layer 230 and border or at least partially surround the lower electrode 310. The ferroelectric layer 320 may be conformally formed on the upper surface of the lower conductive layer 230, the side surface of the lower conductive layer 230, and the upper surface 310U of the lower electrode 310. In some embodiments, the ferroelectric layer 320 may include a ferroelectric material. The ferroelectric material may have directionality according to the electric charges that are stored or charged in the upper electrode 330 and the lower electrode 310.

The upper electrode 330 of the capacitor CAP may border and at least partially surround the ferroelectric layer 320. The upper electrode 330 may be conformally formed on the upper surface and the side surface of the ferroelectric layer 320. The upper electrode 330 may be spaced apart from the lower electrode 310 with the ferroelectric layer 320 therebetween. The upper electrode 330 may be electrically connected to the plate line 400. Accordingly, the electric charges may move to the upper electrode 330 through the plate line 400 and thus may be discharged and charged in the upper electrode 330.

In some embodiments, when the electric charges are stored or charged in the upper electrode 330 and the lower electrode 310, the ferroelectric material of the ferroelectric layer 320 has directionality, and thus, the ferroelectric layer 320 may be polarized. Even when no voltage is applied to the upper electrode 330 and the lower electrode 310, the ferroelectric material of the ferroelectric layer 320 polarized may keep the directionality thereof. However, when the charged electric charges leak from at least one of the upper electrode 330 and the lower electrode 310, the ferroelectric material loses its directionality, and thus, the polarized ferroelectric layer 320 may be depolarized.

An electrode insulating layer 340 of the semiconductor memory device 1000 may be on and at least partially cover the upper electrode 330 of the capacitor CAP. The electrode insulating layer 340 may border or at least partially surround an uppermost surface and the side surface of the upper electrode 330 of the capacitor CAP. The upper surface of the electrode insulating layer 340 may be coplanar with the uppermost surface of the upper electrode 330. The electrode insulating layer 340 may restrict damage to the capacitor CAP from the outside and the generation of noise in the capacitor CAP.

The plate line 400 of the semiconductor memory device 1000 may be formed on the electrode insulating layer 340 and the upper electrode 330. The plate line 400 may be electrically connected to the upper electrode 330. The plate line 400 may be electrically connected to the lower conductive layer 230 through a through via 500. In some embodiments, the through via 500 may extend into or penetrate the electrode insulating layer 340, the upper electrode 330, the ferroelectric layer 320, and the lower electrode 310 and directly contact the plate line 400 and the lower conductive layer 230. For example, an upper surface 500U of the through via 500 may contact a lower surface of the plate line 400, and a lower surface of the through via 500 may contact the upper surface of the lower conductive layer 230.

In some embodiments, an area of the upper surface 500U of the through via 500 may be different from that of the upper surface 310U of the lower electrode 310. The area of the upper surface 500U of the through via 500 may be greater than that of the upper surface 310U of the lower electrode 310. In some embodiments, the upper surface 500U of the through via 500 may be coplanar with an uppermost surface CAPU of the capacitor CAP.

For example, a horizontal width W_500, i.e., a width in the X direction, of the through via 500 may be different from a horizontal width W_CAP, i.e., a width in the X direction, of the capacitor CAP. In some embodiments, the horizontal width W_500 of the through via 500 may be greater than the horizontal width W_CAP of the capacitor CAP.

In some embodiments, the lower conductive layer 230 may be electrically connected to the lower electrode 310 through the landing pad LP and electrically connected to the upper electrode 330 through the through via 500 and the plate line 400. That is, through the plate line 400, the through via 500, and the lower conductive layer 230, overloaded electric charges may move from one of the upper electrode 330 and the lower electrode 310 to another electrode.

In some embodiments, the lower conductive layer 230 may be spaced apart from the upper electrode 330 with the ferroelectric layer 320 therebetween. The lower conductive layer 230 may not directly contact the lower electrode 310. That is, an area of a lower surface of the lower electrode 310 may be the same as or less than an area of the upper surface LPU of the landing pad LP. Accordingly, the ferroelectric layer 320 may be formed on an edge of the upper surface LPU of the landing pad LP.

In some embodiments, between the upper electrode 330 and the lower electrode 310, the combined resistance value of the lower electrode 230, the through via 500, and the plate line 400 may be greater than the resistance value of the active portion AP in the on-state and may be less than the resistance value of the active portion AP in the off-state. For example, the combined resistance value of the lower conductive layer 230, the through via 500, and the plate line 400 may be about 0.1 MΩ to about 5 MΩ. Hereinafter, the combined resistance value refers to a combination of resistance values of resistors through which electric charges pass when the electric charges move between the upper electrode 330 and the lower electrode 310.

In some embodiments, the resistance value of the plate line 400, the resistance value of the lower conductive layer 230, and the resistance value of the through via 500 may be different from each other. In some embodiments, the resistance value of the lower conductive layer 230 may be much greater than the resistance value of the through via 500 and the resistance value of the plate line 400. For example, the resistance value of the lower conductive layer 230 may be about 0.1 MΩ to about 5 MΩ.

Among the plate line 400, the lower conductive layer 230, and the through via 500, the one element with the greatest resistance value may be referred to as a leaker. A path through which the lower electrode 310 is electrically connected to the upper electrode 330 may be the lower conductive layer 230, the through via 500, and the plate line 400. In this case, a resistance value of the path for electric charges between the lower electrode 310 and the upper electrode 330, that is, the combined resistance value of the lower conductive layer 230, the through via 500, and the plate line 400, may be substantially the same as the resistance value of the leaker.

In some embodiments, the greatest resistance value among the resistance values of the lower conductive layer 230, the through via 500, and the plate line 400, specifically, the resistance value of the leaker, may be greater than the resistance value of the active portion AP in the on-state and may be less than the resistance value of the active portion AP in the off-state.

When the active portion AP is in the on-state, the electric charges do not move to the leaker because of the relatively great resistance value of the leaker, and thus, the capacitor CAP may normally perform a write operation. For example, when the active portion AP is in the off-state, the electric charges leaking from the lower electrode 310 may move to the upper electrode 330 through the leaker because of the relatively small resistance value of the leaker, and thus, the depolarization of the ferroelectric layer 320 may be reduced or restricted.

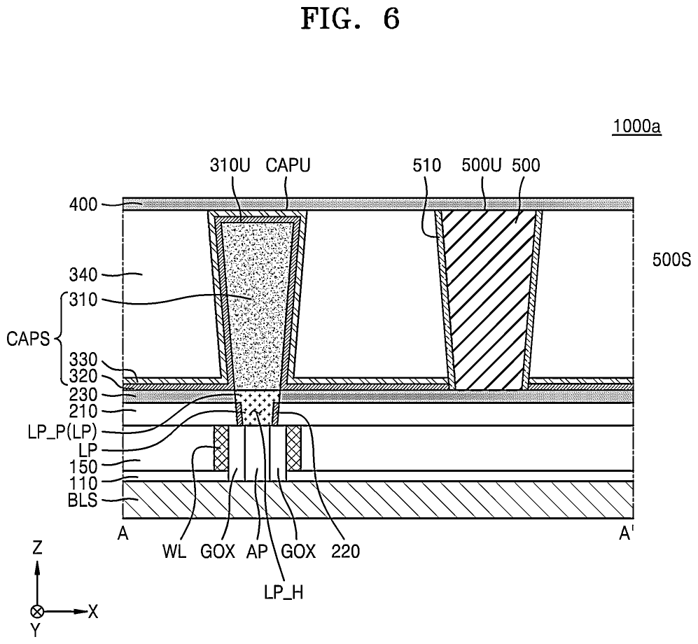

FIG. 6 is a schematic cross-sectional view, taken along the line A-A′ of FIG. 3, of a semiconductor memory device 1000a according to an embodiment.

Referring to FIG. 6, the semiconductor memory device 1000a may include an active portion AP, a pad insulating layer 210, a landing pad LP, a lower conductive layer 230, a capacitor CAP, a through via 500, a lateral conductive layer 510, and a plate line 400.

Most components forming the semiconductor memory device 1000a described below and materials of the components are substantially the same as or similar to those described above with reference to FIG. 5. Therefore, for convenience of explanation, a difference between the semiconductor memory device 1000a of FIG. 6 and the semiconductor memory device 1000 of FIG. 5 is mainly described.

The lateral conductive layer 510 of the semiconductor memory device 1000a may be arranged on a side surface 500S of the through via 500. In some embodiments, the lateral conductive layer 510 may be conformally formed on the side surface 500S of the through via 500.

The lateral conductive layer 510 may be electrically connected to the plate line 400 and the lower conductive layer 230. The lateral conductive layer 510 may have a resistance value different from that of the through via 500. For example, the plate line 400 and the lower conductive layer 230 may be electrically connected to each other by the lateral conductive layer 510 and the through via 500, which have different resistance values.

In some embodiments, the combined resistance value of the lower electrode 230, the through via 500, the lateral conductive layer 510, and the plate line 400 may be greater than the resistance value of the active portion AP in the on-state and may be less than the resistance value of the active portion AP in the off-state. For example, the combined resistance value of the lower conductive layer 230, the through via 500, the lateral conductive layer 510, and the plate line 400 may be from about 0.1 MΩ to about 5 MΩ. Hereinafter, the combined resistance value may refer to the resistance value of the upper electrode 330 to the lower electrode 310.

In some embodiments, the resistance values of the plate line 400, the lower conductive layer 230, the through via 500, and the lateral conductive layer 510 may be different. Among the plate line 400, the lower conductive layer 230, the through via 500, and the lateral conductive layer 510, the one element with the greatest resistance value may be referred to as a leaker. The combined resistance value of the plate line 400, the lower conductive layer 230, the through via 500, and the lateral conductive layer 510 may be substantially the same as the resistance value of the leaker. The combined resistance value of the lower conductive layer 230, the through via 500, the lateral conductive layer 510, and the plate line 400 may be readily adjusted through the lateral conductive layer 510.

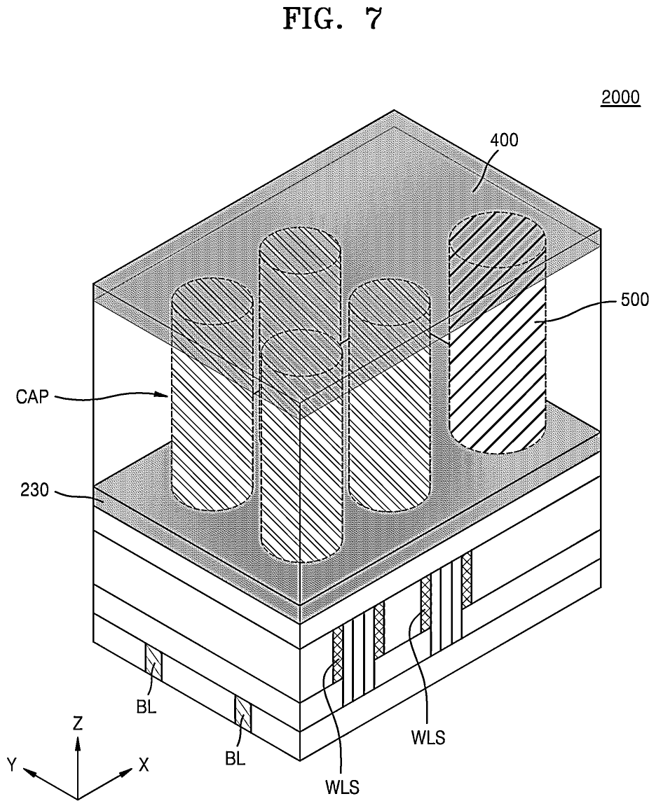

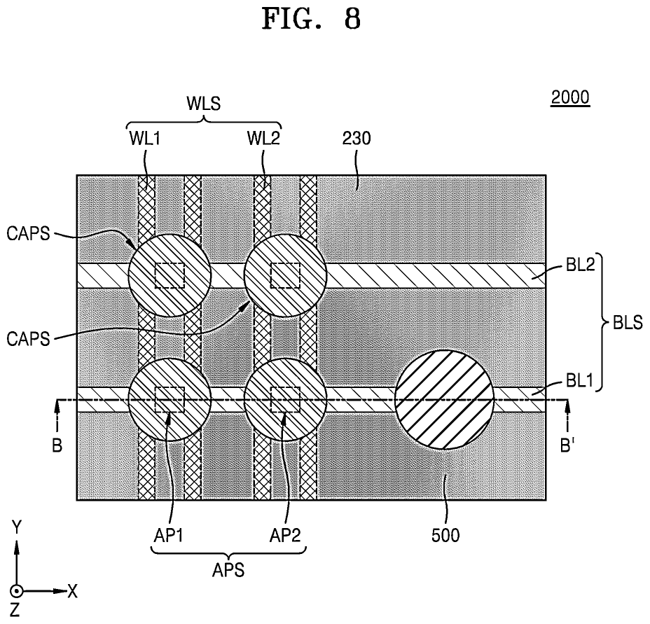

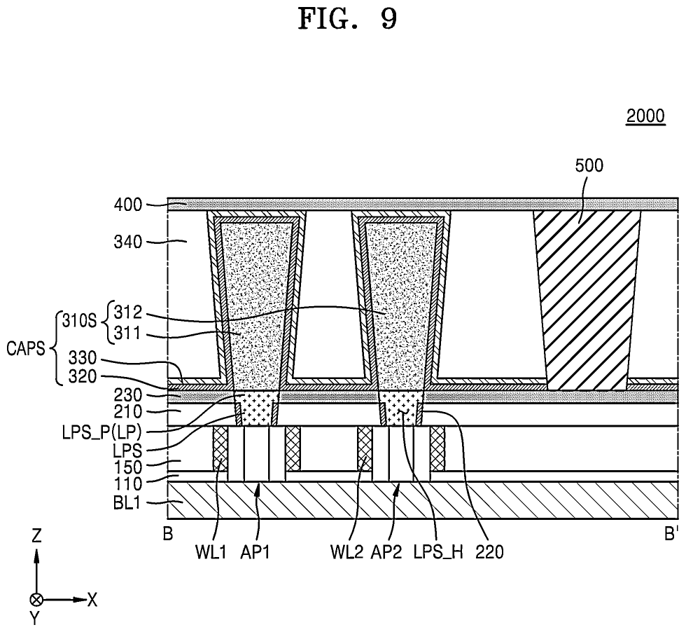

FIG. 7 is a schematic perspective view of a semiconductor memory device 2000 according to an embodiment. FIG. 8 is a schematic layout of the semiconductor memory device 2000 of FIG. 7. FIG. 9 is a schematic cross-sectional view of the semiconductor memory device 2000 of FIG. 8, taken along a line B-B′ of FIG. 8.

Referring to FIGS. 7 to 9, the semiconductor memory device 2000 may include a plurality of active portions APS, a pad insulating layer 210, a plurality of landing pads LPS, a lower conductive layer 230, a plurality of capacitors CAPS, a plate line 400, and a through via 500.

Most components forming the semiconductor memory device 2000 described below and materials of the components are substantially the same as or similar to those described above with reference to FIG. 2. Therefore, for convenience of explanation, a difference between the semiconductor memory device 2000 of FIG. 7 and the semiconductor memory device 1000 of FIG. 2 is mainly described.

The active portions APS may include the active portion (AP of FIG. 4) described above. The landing pads LPS may include the landing pad (LP of FIG. 4) described above. The capacitors CAPS may include the capacitor (CAP of FIG. 4) described above. FIG. 7 illustrates four active portions APS, landing pads LPS, and capacitors CAPS, but the number of each of the active portions APS, the landing pads LPS, and the capacitors CAPS is not limited thereto.

The active portions APS and the capacitors CAPS may be in one-to-one correspondence. Respective landing pads LPS may be arranged between the active portions APS and the capacitors CAPS respectively corresponding to the active portions APS. That is, the landing pads LPS and the active portions APS may be in one-to-one correspondence.

The semiconductor memory device 2000 may include a plurality of bit lines BLS and a plurality of word lines WLS. The bit lines BLS may extend in the first direction (the X direction) and be spaced apart from each other in the second direction (the Y direction). The word lines WLS may extend in the second direction (the Y direction) and be spaced apart from each other in the first direction (the X direction). The bit lines BLS and the word lines WLS may be spaced apart from each other in the vertical direction (the Z direction) with the line insulating layer 110 therebetween.

The active portions APS of the semiconductor memory device 2000 may be formed on the bit lines BLS, respectively. The active portions APS may be formed at intersection points where the bit lines BLS cross the word lines WLS. By selecting some of the bit lines BLS and the word lines WLS, electric charges may flow in some of the active portions APS.

In some embodiments, some of the active portions APS may be formed on a first bit line BL1, and others thereof may be formed on a second bit line BL2. At least two active portions may be formed in each bit line BLS.

In some embodiments, the active portions APS may be formed on the first bit line BL1 and include a first active portion AP1 and a second active portion AP2 that are spaced apart from each other in the first direction (the X direction). The first active portion AP1 may be electrically connected to the first word line WL1, and the second active portion AP2 may be electrically connected to the second word line WL2.

For example, when a signal flows in the first bit line BL1 and the first word line WL1, the electric charges may move in the first active portion AP1 but may not move in the second active portion AP2. However, because of the signal flowing in the first bit line BL1, the electric charges may leak from a capacitor arranged in the second active portion AP2. Such a leakage may be reduced or restricted by the leaker described above, which will be further described below.

The pad insulating layer 210 of the semiconductor memory device 2000 may be located in the active portions APS. The pad insulating layer 210 may include a plurality of pad through holes LPS_H. The pad through holes LPS_H may correspond to the active portions APS, respectively. The landing pads LPS may at least partially fill the inside of the pad through holes LPS_H. Accordingly, the landing pads LPS may correspond to the active portions APS one-to-one.

The lower conductive layer 230 of the semiconductor memory device 2000 may border or at least partially surround the sidewall of the protrusion LPS_P of each landing pad LPS. That is, the lower conductive layer 230 may directly contact the landing pads LPS and be electrically connected thereto.

The capacitors CAPS of the semiconductor memory device 2000 may include a plurality of lower electrodes 310S, a ferroelectric layer 320, and an upper electrode 330. The lower electrodes 310S may correspond to the active portions APS and the landing pads LPS, respectively. That is, the lower electrodes 310S may be arranged on different active portions APS. The ferroelectric layer 320 may border or at least partially surround the lower electrodes 310S and be on and at least partially cover upper surfaces of the lower electrodes 310S. The upper electrode 330 may be formed on the ferroelectric layer 320. In the present specification, a capacitor corresponding to one active portion may be defined as one of the lower electrodes 310S that is formed on the active portion, a portion of the ferroelectric layer 320 that borders or at least partially surrounds the side surface and the upper surface of the above lower electrode, and a portion of the upper electrode 330 that borders or at least partially surrounds the aforementioned portion of the ferroelectric layer 320.

The plate line 400 of the semiconductor memory device 2000 may be located on the capacitors CAPS. The plate line 400 may be electrically connected to the capacitors CAPS. In some embodiments, the plate line 400 may be configured to apply the same voltage to the upper electrode 330 of the capacitors CAPS located in one memory cell area. Because the voltage may be applied to the upper electrodes 330 through the plate line 400, the semiconductor memory device 2000 may be miniaturized.

The plate line 400 may be electrically connected to the lower conductive layer 230 through the through via 500. In some embodiments, the lateral conductive layer (510 of FIG. 6) described above may be located on the side surface of the through via 500. In some embodiments, the cross-section of the through via 500 may be greater than the cross-sectional area of each lower electrode 310S.

The plate line 400 is electrically connected to the lower conductive layer 230, and consequently, the upper electrode 330 and the lower electrodes 310S of the capacitors CAPS may be electrically connected to each other. However, because the combined resistance value of the plate line 400, the through via 500, and the lower conductive layer 230 is relatively great, the polarization and depolarization of each capacitor CAPS may not be affected.

When the one element with the greatest resistance value among the plate line 400, the through via 500, and the lower conductive layer 230 is referred to as a leaker, the resistance value of the leaker may be substantially the same as the combined resistance value of the plate line 400, the through via 500, and the lower conductive layer 230.

In detail, the resistance value of the leaker may be greater than the resistance value of the active portion in the on-state and may be less than the resistance value of the active portion in the off-state. Accordingly, when the active portion is in the on-state, the electric charges do not move to the leaker because of its relatively great resistance value, and thus, the electric charges may be charged to the capacitor normally. Because the leaker has a relatively low resistance value when the active portion is in the off-state, a small amount of electric charges may move, and thus, the leakage of the electric charges to the active portion from the capacitor may be reduced or restricted.

For example, when a signal flows in the first bit line BL1 and the first word line WL1, the first active portion AP1 may be in the on-state, and the second active portion AP2 may be in the off-state. In this case, because the resistance value of the first active portion AP1 is less than that of the leaker, the electric charges may be charged to a first lower electrode 311 of the capacitor that corresponds to the first active portion APL. In some embodiments, in this case, while the electric charges are charged to a second lower electrode 312 of the capacitor that corresponds to the second active portion AP2, the electric charges in the second lower electrode 312 may unintentionally leak to the first bit line BL1.

Because the resistance value of the leaker is less than the resistance value of the second active portion AP2 that is in the off-state, the electric charges leaking from the second lower electrode 312 may move along the leaker, not the second active portion AP2. Accordingly, an area of the upper electrode 330 of the capacitor corresponding to the second active portion AP2 and the total quantity of the electric charges charged to the second lower electrode 312 may be maintained. Finally, by controlling the unintentional leakage of the electric charges from the second lower electrode 312 to the second active portion AP2 that is in the off-state, the unintentional depolarization of the capacitor corresponding to the second active portion AP2 may be controlled.

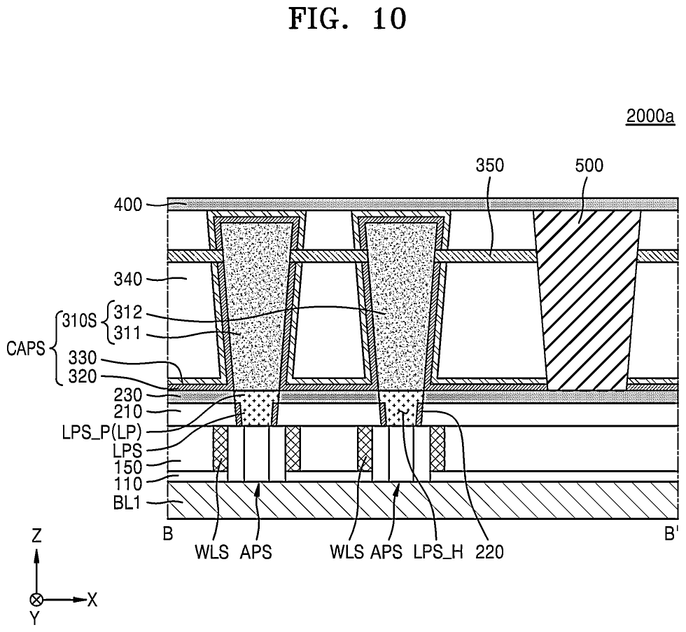

FIG. 10 is a schematic cross-sectional view, taken along the line B-B′ of FIG. 8, of a semiconductor memory device 2000a according to an embodiment.

Referring to FIG. 10, the semiconductor memory device 2000a may include a plurality of active portions APS, a pad insulating layer 210, a plurality of landing pads LPS, a lower conductive layer 230, a plurality of capacitors CAPS, a plate line 400, and a through via 500.

Most components forming the semiconductor memory device 2000a described below and materials of the components are substantially the same as or similar to those described above with reference to FIG. 9. Therefore, for convenience of explanation, a difference between the semiconductor memory device 2000a of FIG. 10 and the semiconductor memory device 2000 of FIG. 9 is mainly described.

The semiconductor memory device 2000a may further include a supporting insulating layer 350. The supporting insulating layer 350 may be located inside the electrode insulating layer 340. The supporting insulating layer 350 may support a plurality of lower electrodes 310S of the capacitors CAPS.

In some embodiments, the supporting insulating layer 350 may contact a portion of a side surface of each of the lower electrode 310S of the capacitors CAPS and extend planarly. For example, the length of the supporting insulating layer 350 in the vertical direction (the Z direction) may be less than the length thereof in the horizontal directions (the X direction and the Y direction). In some embodiments, the supporting insulating layer 350 may be closer to the plate line 400 than the lower conductive layer 230.

The supporting insulating layer 350 may contact a portion of a side surface of each lower electrode 310S and contact all of the lower electrodes 310S. The supporting insulating layer 350 may support the lower electrodes 310S in the process of forming the capacitors CAPS. The breakage or bending of the lower electrodes 310S may be controlled using the supporting insulating layer 350.

In some embodiments, materials forming the supporting insulating layer 350 may include SiN, SiO, SiCN, SiBN, SiON, SiOCN, SiBCN, SiOC, or a combination thereof.

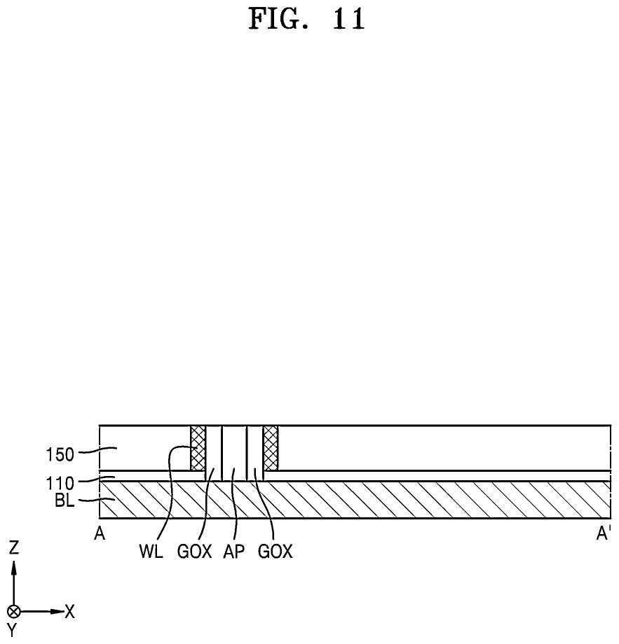

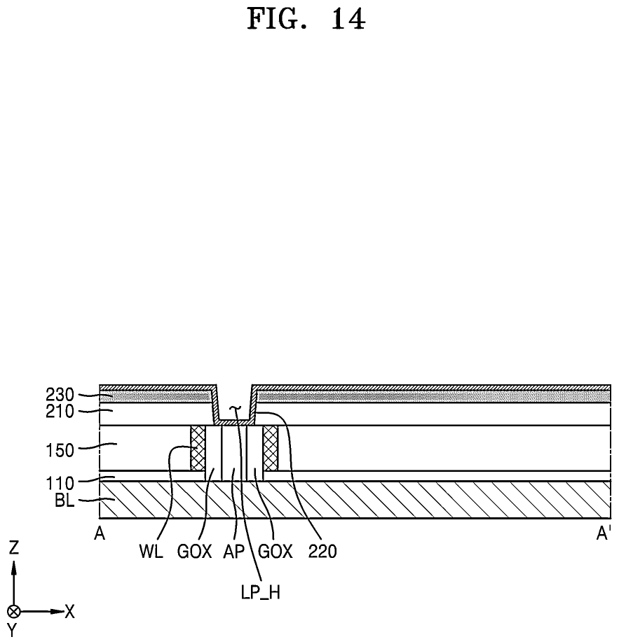

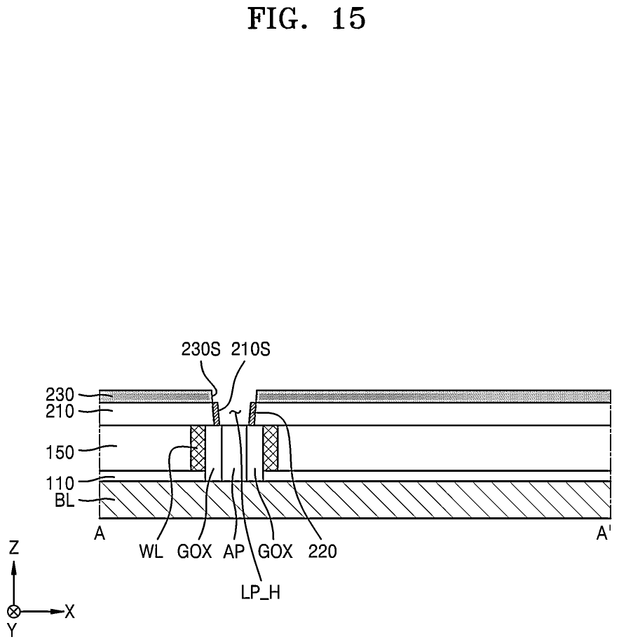

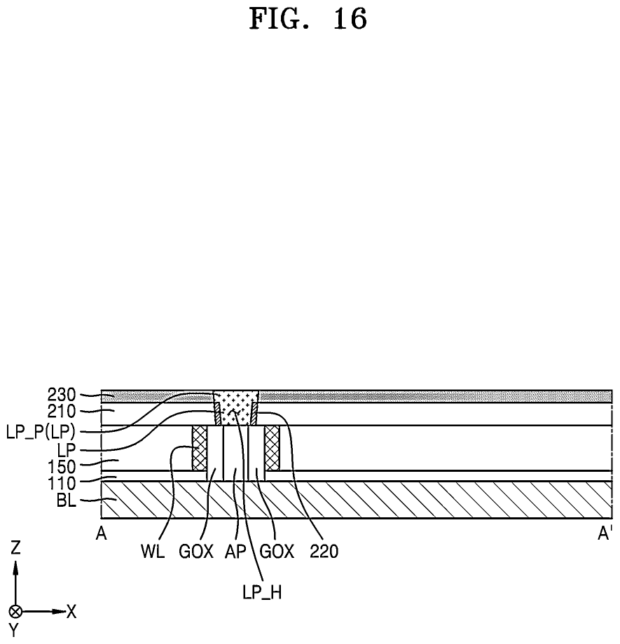

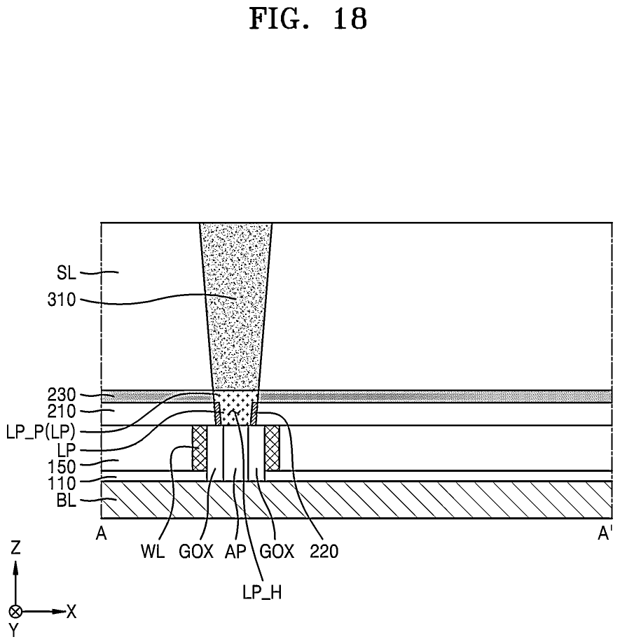

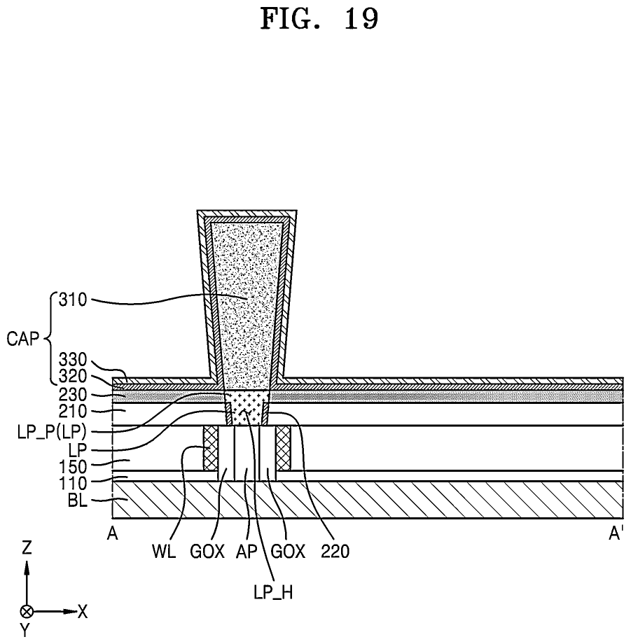

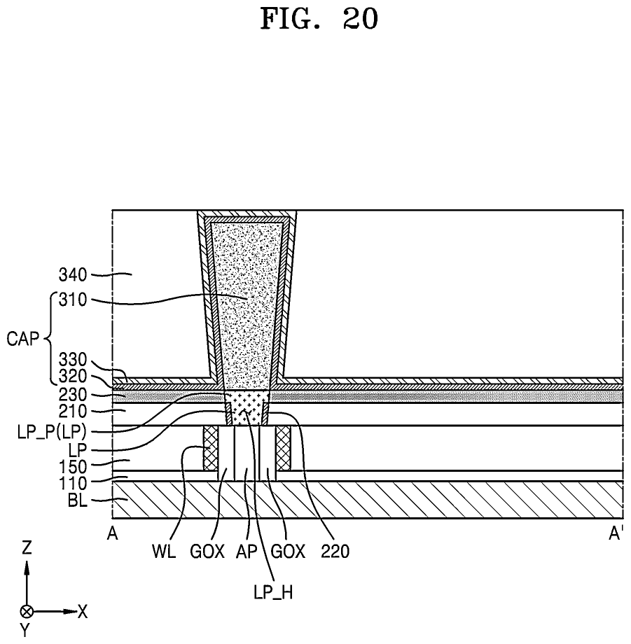

FIGS. 11 to 22 are diagrams showing, in an example process order, a method of manufacturing the semiconductor memory device 1000, according to an embodiment. In detail, the diagrams of FIGS. 11 to 22 are cross-sectional views of the semiconductor memory device 1000 of FIG. 2, taken along the line A-A′ of FIG. 3.

Referring to FIG. 11, the active portion AP and the word line WL may be formed on the bit line BL.

The active portion AP may be patterned to be located on the bit line BL by covering a substrate, in which the bit line BL is formed, with the active portion AP and performing photolithography and etching on the active portion AP. Next, the gate insulating layer GOX extending in the second direction (the Y direction) may be deposited on both sides of the active portion AP, and the line insulating layer 110 may be formed to border or at least partially surround the side surface of the gate insulating layer GOX. Then, after an upper portion of the line insulating layer 110 is partially removed, the word line WL located on the line insulating layer 110 and separated from the active portion AP with the gate insulating layer GOX therebetween may be formed. The insulating layer 150 may be formed to border or at least partially surround the side surface of the word line WL.

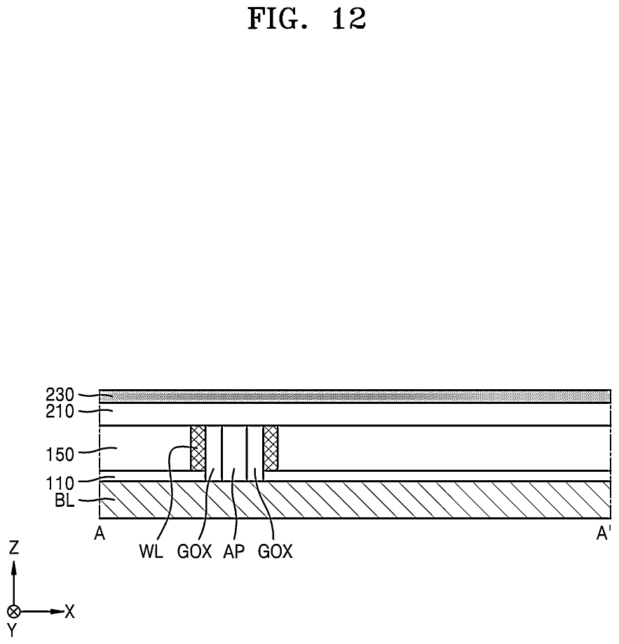

Referring to FIGS. 12 to 16, the landing pad LP and the lower conductive layer 230 may be formed on the upper portion of the active portion AP.

Through a deposition process, the pad insulating layer 210 and the lower conductive layer 230 may be formed on the insulating layer 150. Next, a through hole extending into or penetrating the pad insulating layer 210 and the lower conductive layer 230 may be formed. In this case, the through hole may include the pad through hole LP_H of the pad insulating layer 210 and the through hole of the lower conductive layer 230.

In some embodiments, because the through hole extending into or penetrating the pad insulating layer 210 and the lower conductive layer 230 is formed once through photolithography and an etching process, the inner wall of the pad through hole LP_H of the pad insulating layer 210 may be coplanar with the inner wall of the through hole of the lower conductive layer 230. For example, the inner wall of the through hole of the lower conductive layer 230 may be the side surface 230S of the lower conductive layer 230 which contacts the protrusion LP_P of the landing pad LP.

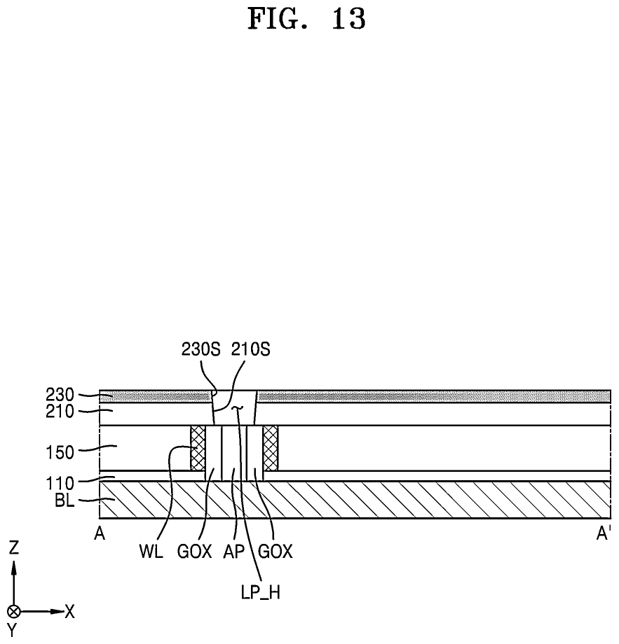

Next, the spacer 220 may be conformally deposited on the resulting structure of FIG. 13. In detail, the spacer 220 may be conformally formed on an exposed portion of the upper surface and the side surface 230S of the lower conductive layer 230, the side surface 210S of the pad insulating layer 210 that defines the pad through hole LP_H, and the upper surface of the active portion AP.

Then, a portion of the spacer 220 may be removed to expose the upper surface of the active portion AP and the through hole of the lower conductive layer 230. Accordingly, the spacer 220 may only remain on the side surface 210S of the pad insulating layer 210 that defines the pad through hole LP_H. In some embodiments, in the process of removing the spacer 220, an upper portion of the spacer 220 is removed relatively more in a thickness direction, such that a thickness of the spacer 220 may decrease closer to the lower conductive layer 230.

Next, the landing pad LP may be formed to at least partially fill an empty space of the through hole penetrating the pad insulating layer 210 and the lower conductive layer 230. A portion of the landing pad LP that is located inside the through hole of the lower conductive layer 230 may be referred to as the protrusion LP_P. The protrusion LP_P of the landing pad LP may contact the upper surface of the spacer 220 and the side surface 230S of the lower conductive layer 230. In some embodiments, the upper surface of the landing pad LP may be coplanar with the upper surface of the lower conductive layer 230. In some embodiments, through a plating process, the landing pad LP may be formed in the empty space of the through hole extending into or penetrating the pad insulating layer 210 and the lower conductive layer 230.

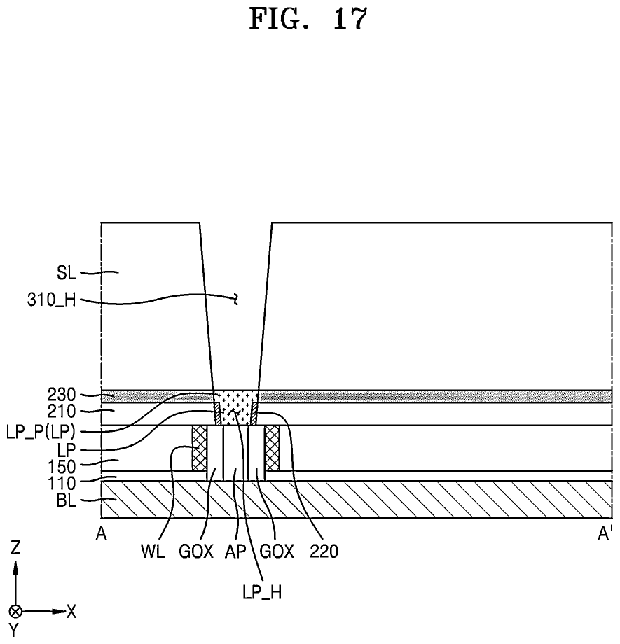

Referring to FIGS. 17 to 20, the capacitor CAP may be formed on the landing pad LP.

After a sacrificial layer SL is deposited to be on and at least partially cover the lower conductive layer 230, an electrode through hole 310_H, in which the lower electrode 310 is to be formed, may be formed through photolithography and etching. In some embodiments, the electrode through hole 310_H may have a tapered shape in which the horizontal width of the electrode through hole 310_H decreases closer to the lower conductive layer 230.

Next, through the plating process and/or the deposition process, the lower electrode 310 filling the electrode through hole 310_H may be formed. The lower electrode 310 may directly contact the landing pad LP and be electrically connected thereto.

Next, the sacrificial layer SL may be removed, and the ferroelectric layer 320 and the upper electrode 330 may be formed on the lower conductive layer 230 and the lower electrode 310. In some embodiments, the ferroelectric layer 320 may be conformally formed on the upper surface of the lower conductive layer 230 and the side surface and the upper surface of the lower electrode 310 through the deposition process. Through the deposition process, the upper electrode 330 may be conformally formed on the upper surface and the side surface of the ferroelectric layer 320. The lower electrode 310 and the upper electrode 330 may be separated from each other with the ferroelectric layer 320 therebetween.

In some embodiments, when the supporting insulating layer (350 of FIG. 10) remains inside the sacrificial layer SL, the supporting insulating layer may still remain after the removal of the sacrificial layer SL and thus support the lower electrode 310 of the capacitor CAP.

Next, the electrode insulating layer 340 may be formed to protect the capacitor CAP from the outside and restrict the generation of noise. The electrode insulating layer 340 may be on and at least partially cover the side surface of the capacitor CAP. In some embodiments, when the electrode insulating layer 340 is also formed on the upper portion of the capacitor CAP, a portion of the electrode insulating layer 340 may be removed to at least partially expose the uppermost surface of the upper electrode 330 of the capacitor CAP to the outside. Accordingly, the upper surface of the electrode insulating layer 340 may be coplanar with the uppermost surface of the upper electrode 330 of the capacitor CAP.

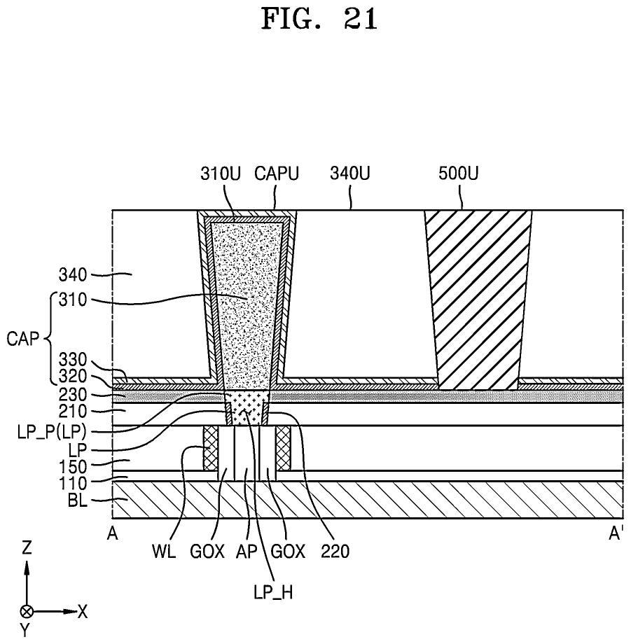

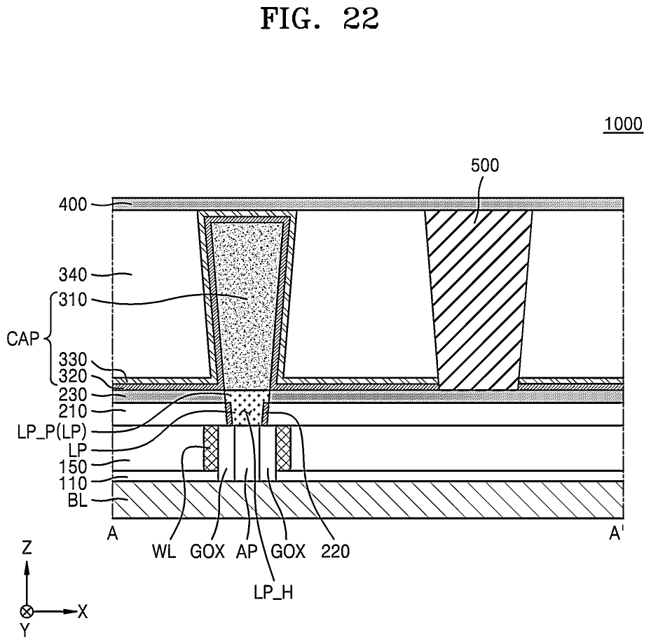

Referring to FIGS. 21 and 22, the plate line 400 electrically connected to the lower conductive layer 230 through the through via 500 may be formed.

A through hole separated from the capacitor CAP of the electrode insulating layer 340 may be formed, and the through via 500 at least partially filling the through hole may be formed through the plating process and/or the deposition process. The through via 500 may directly contact the lower conductive layer 230 and be electrically connected thereto.

In some embodiments, the area of the upper surface 500U of the through via 500 may be greater than the area of the upper surface 310U of the lower electrode 310. In some embodiments, the horizontal width, i.e., the width in the X direction, of the through via 500 may be greater than that of the capacitor CAP.

In some embodiments, the horizontal width, i.e., the width in the X direction, of the through via 500 may decrease closer to the lower conductive layer 230. In some embodiments, the upper surface 500U of the through via 500, the uppermost surface CAPU of the capacitor CAP, and the upper surface 340U of the electrode insulating layer 340 may be coplanar.

In some embodiments, the lateral conductive layer (510 of FIG. 6) may be formed first in the through hole of the electrode insulating layer 340, and then, the through hole 500 may be formed in the empty space. The resistance value of the lateral conductive layer (510 of FIG. 6) may be different from the resistance value of the through via 500.

Next, the plate line 400 may be formed on the through via 500, the capacitor CAP, and the electrode insulating layer 340. The plate line 400 may be electrically connected to the capacitor CAP and the through via 500. The plate line 400 may be electrically connected to the lower conductive layer 230 through the through via 500. The lower electrode 310 and the upper electrode 330 of the capacitor CAP may be electrically connected to each other through the plate line 400, the through via 500, and the lower conductive layer 230.

In some embodiments, the combined resistance of the plate line 400, the through via 500, and the lower conductive layer 230 may be greater than the resistance of the active portion AP when the active portion AP is in the on-state and may be less than the resistance of the active portion AP when the active portion AP is in the off-state. For example, a combined resistance value of the lower conductive layer 230, the through via 500, and the plate line 400 may be 0.1 MΩ to 5 MΩ.

While embodiments of the inventive concept have been particularly shown and described with reference to embodiments thereof, it will be understood that various changes in form and details may be made therein without departing from the spirit and scope of the following claims.

What is claimed is:

1. A semiconductor memory device comprising:
an active portion;
a pad insulating layer on the active portion and comprising a pad through hole;
a landing pad in the pad through hole and electrically connected to the active portion, the landing pad comprising a protrusion protruding towards an upper portion of the pad insulating layer;
a lower conductive layer on the pad insulating layer and bordering a side surface of the protrusion of the landing pad;
a lower electrode on the landing pad and electrically connected to the landing pad;
a ferroelectric layer on the lower conductive layer and bordering the lower electrode;
an upper electrode bordering the ferroelectric layer;
an electrode insulating layer on the upper electrode; and
a plate line on the electrode insulating layer and the upper electrode and electrically connected to the upper electrode,
wherein the plate line is electrically connected to the lower conductive layer through a through via.

2. The semiconductor memory device of claim 1, wherein a resistance value of the lower conductive layer is greater than a resistance value of the landing pad and a resistance value of the lower electrode.

3. The semiconductor memory device of claim 1, wherein a resistance value of the lower conductive layer, the through via, or the plate line is different from a resistance value of other ones of the lower conductive layer, the through via, and the plate line, and
a greatest resistance value among the resistance value of the lower conductive layer, the resistance value of the through via, and the resistance value of the plate line is greater than a resistance value of the active portion when the active portion is in an on-state and is less than the resistance value of the active portion when the active portion is in an off-state.

4. The semiconductor memory device of claim 1, wherein a greatest resistance value among the resistance value of the lower conductive layer, the resistance value of the through via, and the resistance value of the plate line is about 0.1 MΩ to about 5 MΩ.

5. The semiconductor memory device of claim 1, wherein the through via extends into the electrode insulating layer, the upper electrode, and the ferroelectric layer and directly contacts the plate line and the lower conductive layer.

6. The semiconductor memory device of claim 5, wherein the upper electrode is electrically connected to the lower electrode through the lower conductive layer, the through via, and the plate line when the active portion is in an off-state.

7. The semiconductor memory device of claim 5, further comprising a lateral conductive layer that is conformally positioned on a side surface of the through via and has a resistance value that is different from a resistance value of the through via,
wherein the lateral conductive layer is electrically connected to the plate line and the lower conductive layer.

8. The semiconductor memory device of claim 7, wherein a greatest resistance value among the resistance value of the lower conductive layer, the resistance value of the lateral conductive layer, the resistance value of the through via, and the resistance value of the plate line is greater than a resistance value of the active portion when the active portion is in an on-state and is less than the resistance value of the active portion when the active portion is in an off-state.

9. The semiconductor memory device of claim 1, wherein an upper surface of the lower conductive layer is coplanar with an upper surface of the landing pad.

10. The semiconductor memory device of claim 1, wherein a side surface of the lower conductive layer that contacts the protrusion of the landing pad is coplanar with a side surface of the pad insulating layer that defines the pad through hole.

11. The semiconductor memory device of claim 1, further comprising a spacer positioned on a sidewall of the pad insulating layer that defines the pad through hole.

12. The semiconductor memory device of claim 11, wherein the protrusion of the landing pad is on an upper surface of the spacer.

13. The semiconductor memory device of claim 1, wherein the lower conductive layer is spaced apart from the upper electrode with the ferroelectric layer therebetween.

14. The semiconductor memory device of claim 1, wherein the lower conductive layer does not directly contact the lower electrode.

15. A semiconductor memory device comprising:
a plurality of bit lines extending in a first direction and spaced apart from each other in a second direction perpendicular to the first direction;
a plurality of active portions, at least two of the plurality of active portions being on the plurality of bit lines, respectively;
a pad insulating layer on the plurality of active portions and comprising a plurality of pad through holes corresponding to the plurality of active portions;
a plurality of landing pads in the plurality of pad through holes and electrically connected to the plurality of active portions, respectively, and comprising a plurality of protrusions protruding towards an upper portion of the pad insulating layer;
a lower conductive layer bordering side surfaces of the plurality of protrusions of the plurality of landing pads;
a plurality of lower electrodes on the plurality of landing pads, respectively, and electrically connected to the plurality of landing pads;
a ferroelectric layer bordering the plurality of lower electrodes and being on the lower conductive layer;
an upper electrode bordering the ferroelectric layer;
an electrode insulating layer on the upper electrode; and
a plate line on the electrode insulating layer and the upper electrode and electrically connected to the upper electrode,
wherein the plate line is electrically connected to the lower conductive layer through a through via, and
wherein the lower conductive layer, the through via, and the plate line electrically connect the lower electrode to the upper electrode when the active portion is in an off-state.

16. The semiconductor memory device of claim 15, wherein an area of an upper surface of the through via is greater than an area of an upper surface of one of the plurality of lower electrodes.

17. The semiconductor memory device of claim 15, further comprising a supporting insulating layer inside the electrode insulating layer and configured to support the lower electrode.

18. The semiconductor memory device of claim 17, wherein the lower conductive layer is electrically connected to the plurality of lower electrodes and the upper electrode, and
a resistance value of the lower conductive layer is greater than a resistance value of the plurality of lower electrodes and a resistance value of the plurality of landing pads.

19. A semiconductor memory device comprising:
a plurality of bit lines extending in a first direction and spaced apart from each other in a second direction perpendicular to the first direction;
a plurality of word lines extending in the second direction and spaced apart from each other in the first direction;
a plurality of active portions, at least two of the plurality of active portions being on the plurality of bit lines, respectively;
a plurality of gate insulating layers on both sides of the plurality of active portions, respectively;
a pad insulating layer on the plurality of active portions and comprising a plurality of pad through holes corresponding to the plurality of active portions;
a plurality of landing pads in the plurality of pad through holes and electrically connected to the plurality of active portions, respectively, and comprising a plurality of protrusions protruding towards an upper portion of the pad insulating layer;
a lower conductive layer bordering side surfaces of the plurality of protrusions of the plurality of landing pads;
a plurality of lower electrodes on the plurality of landing pads, respectively, and electrically connected to the plurality of landing pads;
a ferroelectric layer bordering the plurality of lower electrodes and being on the lower conductive layer;
an upper electrode bordering the ferroelectric layer;
an electrode insulating layer on the upper electrode; and
a plate line on the electrode insulating layer and the upper electrode and electrically connected to the upper electrode,
wherein the plurality of word lines are spaced apart from the plurality of active portions with the plurality of gate insulating layers therebetween,
wherein a width of the plurality of protrusions in the first direction is greater than a width of a portion of the plurality of landing pads in the first direction that is located in the plurality of pad through holes, and
wherein the plate line is electrically connected to the lower conductive layer through a through via with a greater width in the first direction than the lower conductive layer.

20. The semiconductor memory device of claim 19, wherein a combined resistance value of the lower conductive layer, the through via, and the plate line, which electrically connect the plurality of lower electrodes to the upper electrode, is greater than a resistance value of the active portion when the active portion is in an on-state and is less than the resistance value of the active portion when the active portion is in an off-state.
